(19) United States
(12) Patent Application Publication
(10) Pub. No.: US 2026/0180511 A1
(43) Pub. Date: Jun. 25, 2026

(54) POWER AMPLIFIER CIRCUIT AND TRANSMISSION CIRCUIT HAVING THE POWER AMPLIFIER CIRCUIT INSTALLED THEREIN

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(21) Appl. No.: 19/537,725

(22) Filed: Feb. 12, 2026

Related U.S. Application Data
(63) Continuation of application No. PCT/JP2024/026450, filed on Jul. 24, 2024.

(30) Foreign Application Priority Data
Aug. 31, 2023 (JP) 2023-140778

(51) Int. Cl. H03F 1/02; H03F 1/56

(52) U.S. Cl. CPC H03F 1/0205; H03F 1/0277; H03F 1/0288; H03F 1/565

(57) ABSTRACT

A power amplifier circuit includes an input terminal, an output terminal, amplifiers, a balun, and semiconductor substrates. The amplifier amplifies a radio-frequency signal received at the input terminal. The amplifier further amplifies the radio-frequency signal amplified by the first amplifier. The balun is connected to the amplifier and converts an unbalanced line into two balanced lines. The amplifier and the amplifier are formed on the semiconductor substrate. One of the balanced lines is connected to a terminal of the output terminal. The other of the balanced lines is connected to a terminal of the output terminal. The frequency of a radio-frequency signal to be transmitted is 100 GHz or more. The balun is formed on the semiconductor substrate.

### CROSS REFERENCE TO RELATED APPLICATION

This is a continuation of International Application No. PCT/JP2024/026450 filed on Jul. 24, 2024 which claims priority from Japanese Patent Application No. 2023-140778 filed on Aug. 31, 2023. The contents of these applications are incorporated herein by reference in their entireties.

### BACKGROUND OF THE DISCLOSURE

### Field of the Disclosure

The present disclosure relates to a power amplifier circuit and a transmission circuit having the power amplifier circuit installed therein. More specifically, the present disclosure relates to a configuration of the power amplifier circuit appropriate for a radio-frequency signal in a sub-terahertz frequency band.

### Description of the Related Art

Japanese Unexamined Patent Application Publication No. 2023-10120 discloses radio equipment capable of transmitting a radio-frequency signal having a frequency of 300 GHz or more. In the radio equipment disclosed in Japanese Unexamined Patent Application Publication No. 2023-10120, a differential amplifier for amplifying a radio-frequency signal to be transmitted is formed on an InP substrate to improve the antenna gain for the radio-frequency signal of 300 GHz or more.

### BRIEF SUMMARY OF THE DISCLOSURE

In a radio communication apparatus, development of communication in a so-called sub-terahertz frequency band of 100 GHz or more has been advanced in recent years. Since use of the sub-terahertz frequency band enables a spectrum band width to be broadened, it is possible to realize high-speed communication of large capacity of, for example, 100 Gbps or more.

Radio waves generally have characteristics in which the radio waves are attenuated in proportion to square of frequency and square of distance in a free space. A power amplifier used to radiate the radio waves also exposes characteristics in which the gain, the output power, and the efficiency are reduced with the increasing frequency in the sub-terahertz frequency band. Accordingly, in the radiation of a signal of a frequency band of 100 GHz or more, it is necessary to shorten a transmission path between the power amplifier and an antenna (a radiating element) as much as possible in order to reduce the loss of the transmission path as much as possible.

The power amplifier is normally designed so as to operate at fixed impedance (load), such as 50Ω. However, practically, load fluctuation may occur due to proximity of an external object, such as a hand, to the antenna. In the case of an array antenna using multiple radiating elements, the load fluctuation caused by unnecessary mutual coupling between the radiating elements may occur in beam forming. If such load fluctuation occurs, the Q value is decreased due to return loss caused by the difference from the impedance in design to reduce antenna characteristics. Since the power amplifier is directly affected by the load fluctuation when the power amplifier is connected to the radiating element at close range, as in the above case, it may be difficult to realize desired characteristics.

In order to resolve the above problems, it is a possible benefit of the present disclosure to suppress reduction in characteristics caused by the load fluctuation over a wide band in a power amplifier circuit for a transmission circuit supporting the sub-terahertz frequency band.

A power amplifier circuit according to an aspect of the present disclosure includes an input terminal, a first output terminal and a second output terminal, a first amplifier and a second amplifier, a balun, and a semiconductor substrate. The first amplifier amplifies a radio-frequency signal received at the input terminal. The second amplifier further amplifies the radio-frequency signal amplified by the first amplifier. The balun is connected to the second amplifier and converts an unbalanced line into a first balanced line and a second balanced line. The first amplifier and the second amplifier are formed on the semiconductor substrate. The first balanced line is connected to the first output terminal. The second balanced line is connected to the second output terminal. The frequency of a radio-frequency signal to be transmitted is 100 GHz or more. The balun is formed on the semiconductor substrate.

A power amplifier circuit according to another aspect of the present disclosure includes an input terminal, a first output terminal and a second output terminal, a first amplifier and a second amplifier, a balun, and a semiconductor substrate. The first amplifier amplifies a radio-frequency signal received at the input terminal. The second amplifier further amplifies the radio-frequency signal amplified by the first amplifier. The balun is connected to the second amplifier and converts an unbalanced line into a first balanced line and a second balanced line. The first amplifier and the second amplifier are formed on the semiconductor substrate. The first balanced line is connected to the first output terminal. The second balanced line is connected to the second output terminal. The balun is formed on the semiconductor substrate.

In the power amplifier circuit according to the present disclosure, new poles are capable of being formed near the resonant frequency of a load due to the resonance of a balun provided at the downstream of the amplifier. Accordingly, it is possible to widen the frequency band having a return loss lower than or equal to a certain value when the load side is viewed from the output of the amplifier. Consequently, it is possible to suppress reduction in characteristics caused by the load fluctuation over a wide band in the power amplifier circuit used in a transmission circuit supporting the sub-terahertz frequency band.

### BRIEF DESCRIPTION OF THE SEVERAL VIEWS OF THE DRAWINGS

FIG. 1 is a circuit diagram of a transmission circuit to which a power amplifier circuit according to a first embodiment is applied.

FIG. 2 is a transparent side view of the transmission circuit in FIG. 1.

FIG. 3 is a plan view of a first example of a balun in FIG. 1.

FIG. 4 is a plan view of a second example of the balun in FIG. 1.

FIG. 5 is a diagram for describing an example of variation in power and efficiency when an amplifier is directly connected to a radiating element.

FIG. 6 is a table for describing load fluctuation and power fluctuation of the amplifier when a reflection coefficient of the radiating element is varied.

FIG. 7 includes diagrams for describing antenna characteristics in a case in which the amplifier is directly connected to the radiating element and in the transmission circuit of the first embodiment.

FIG. 8 is a transparent side view of a transmission circuit of a first modification.

FIG. 9 is a transparent side view of a transmission circuit of a second modification.

FIG. 10 is a circuit diagram of a transmission circuit to which a power amplifier circuit according to a second embodiment is applied.

FIG. 11 is a plan view of an example of a balun in FIG. 10.

FIG. 12 includes diagrams for describing impedance change of a choke balun of the first embodiment and a Marchand balun of the second embodiment.

### DETAILED DESCRIPTION OF THE DISCLOSURE

Embodiments of the present disclosure will herein be described in detail with reference to the drawings. The same reference numerals are added to the same components or similar components in the drawings and description of such components is not repeated.

### First Embodiment

### (Configuration of Transmission Circuit and Power Amplifier Circuit)

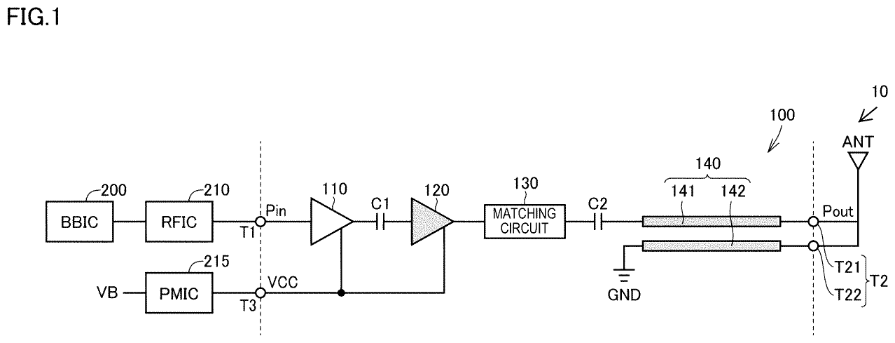

FIG. 1 is a circuit diagram of a transmission circuit 10 to which a power amplifier circuit 100 according to a first embodiment is applied. The transmission circuit 10 is installed in a mobile terminal, such as a mobile phone, a smartphone, or tablet, or a communication device, such as a personal computer, having a communication function.

Referring to FIG. 1, the transmission circuit 10 includes an antenna ANT, a radio frequency integrated circuit (RFIC) 210, which is a power supply circuit, a power management integrated circuit (PMIC) 215 that performs power control, and a baseband integrated circuit (BBIC) 200 composing a baseband signal processing circuit, in addition to the power amplifier circuit 100.

The transmission circuit 10 up-converts an intermediate frequency (IF) signal transmitted from the BBIC 200 into a radio-frequency (RF) signal with the RFIC 210, amplifies the radio-frequency signal with the power amplifier circuit 100, and radiates the amplified radio-frequency signal from the antenna ANT. The transmission circuit 10 of the first embodiment is a device supporting a 6th Generation Mobile Communication System (6G). In other words, the transmission circuit 10 targets at a signal in a so-called sub-terahertz frequency band of 100 GHz or more.

The power amplifier circuit 100 includes an input terminal T1, an output terminal T2, a power terminal T3, amplifiers 110 and 120, a matching circuit 130, a balun 140, and capacitors C1 and C2. The power amplifier circuit 100 receives an input signal Pin from the RFIC 210 at the input terminal T1, amplifies the input signal Pin, and outputs the amplified input signal Pin to the antenna ANT from the output terminal T2.

The PMIC 215 is a power circuit for supplying driving power to operate the power amplifier circuit 100. The PMIC 215 includes, for example, multiple direct current-direct current (DC-DC) converters and converts battery voltage VB supplied from an external battery into multiple different voltage levels in accordance with the magnitude of the signal transmitted from the BBIC 200. The PMIC 215 supplies power supply voltage VCC to the power terminal T3 of the power amplifier circuit 100. The power supply voltage VCC is used as a driving power source for the amplifiers in the power amplifier circuit 100.

The amplifier 110 is an amplifier at a drive stage. The amplifier 110 amplifies the input signal Pin, which is the radio-frequency signal received at the input terminal T1, to drive a power transistor included in the amplifier 120. The radio-frequency signal amplified by the amplifier 110 is transmitted to the amplifier 120 through the DC-cut capacitor C1.

The amplifier 120 is an amplifier at a final stage. The amplifier 120 amplifies the radio-frequency signal amplified by the amplifier 110 to amplify the radio-frequency signal to power required for output from the antenna ANT.

The matching circuit 130 is a circuit that performs impedance matching between output impedance from the amplifier 120 and impedance at the antenna ANT. For example, transmission line transformers (TLT) are used as the matching circuit 130. The matching circuit 130 is connected to the balun 140 via the DC-cut capacitor C2.

The balun 140 is a circuit for converting an unbalanced line into a pair of balanced lines. The balun 140 in the power amplifier circuit 100 is a two-line choke balun including two lines: a line 141 (a first line) and a line 142 (a second line). One end of the line 141 is connected to the capacitor C2 and the other end thereof is connected to a terminal T21 of the output terminal T2. One end of the line 142 is connected to ground potential GND and the other end thereof is connected to a terminal T22 of the output terminal T2.

When the wavelength of a radio-frequency signal to be transmitted is denoted by λ, the line lengths of the lines 141 and 142 are set to λ/4, and the line 141 and the line 142 are disposed so as to be magnetically coupled to each other. As a result, a signal the phase of which is inverted with respect to the signal transmitted through the line 141 is induced on the line 142. Accordingly, differential signals having the phases inverted are outputted from the output terminal T2. The balun 140 is capable of functioning as a matching circuit.

The antenna ANT is a two-power-supply antenna that operates in response to the differential signals. The antenna ANT is, for example, a plate-shaped patch antenna or a dipole antenna. The antenna ANT radiates radio waves in response to the differential signals from the power amplifier circuit 100.

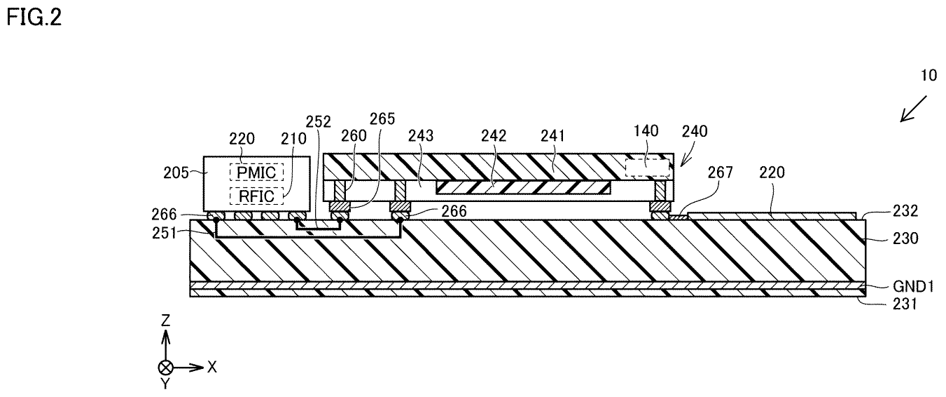

FIG. 2 is a transparent side view of the transmission circuit 10 described above with reference to FIG. 1. Referring to FIG. 2, the transmission circuit 10 includes a radiating element 220, a dielectric substrate 230, a System in Package (SiP) module 205, and an amplifier module 240 in which the power amplifier circuit 100 is formed. In the transparent side views in FIG. 2 and the subsequent diagrams, a normal direction of a main surface of the dielectric substrate 230 is the Z axis and a plane vertical to the Z axis is an XY plane. Referring to FIG. 2, the right and left direction is the X-axis direction and the depth direction is the Y-axis direction.

The dielectric substrate 230 has two main surfaces: a main surface 231 (a first surface) and a main surface 232 (a second surface) that are opposed to each other. The dielectric substrate 230 is a low temperature co-fired ceramics (LTCC) multilayer substrate, a multilayer resin substrate formed by laminating multiple resin layers made of resin, such as epoxy or polyimide, a multilayer resin substrate formed by laminating multiple resin layers made of liquid crystal polymer (LCP) having lower permittivity, a multilayer resin substrate formed by laminating multiple resin layers made of fluorocarbon resin, or a ceramic multilayer substrate other than the LTCC. The dielectric substrate 230 does not necessarily have a multilayer structure and may be composed of a single-layer substrate.

The radiating element 220 corresponds to the antenna ANT in FIG. 1. The radiating element 220 is disposed on the main surface 232 (the face in the positive direction of the Z axis) of the dielectric substrate 230. In the example in FIG. 2, the radiating element 220 is a plate-shaped patch antenna. Although the example is illustrated in FIG. 2 in which the radiating element 220 is exposed from the main surface 232, the radiating element 220 may be disposed on an inner layer of the dielectric substrate 230.

In the dielectric substrate 230, a ground electrode GND1 is disposed so as to be opposed to the radiating element 220 over the entire surface of a dielectric layer between the radiating element 220 and the main surface 232.

The amplifier module 240 includes a semiconductor substrate 241 and a semiconductor substrate 242. The semiconductor substrate 242 is disposed on the main surface in the negative direction of the Z axis of the semiconductor substrate 241 and is electrically connected to the semiconductor substrate 241. The semiconductor substrate 242 is molded with insulating resin 243 on the semiconductor substrate 241.

The amplifier module 240 is mounted on the main surface 232 of the dielectric substrate 230. The semiconductor substrate 241 is electrically connected to the dielectric substrate 230 via columnar electrodes 260, which are disposed in the resin 243 for molding, connection electrodes 265, and solder bumps 266.

The semiconductor substrate 241 is a semiconductor substrate made of an Si-based base material, such as silicon germanium (SiGe). In contrast, the semiconductor substrate 242 is a semiconductor substrate containing a base material of a material having a compound of a Group III element and a Group V element (hereinafter also referred to as “a Group III-V compound), such as gallium nitride (GaN), gallium arsenide (GaAs), or indium phosphide (InP), as the major component.

The final-stage amplifier 120 in the power amplifier circuit 100 in FIG. 1 is formed on the semiconductor substrate 242. In contrast, the circuits other than the amplifier 120 in the power amplifier circuit 100 are formed on the semiconductor substrate 241. Accordingly, the balun 140 is also formed on the semiconductor substrate 241.

The radio-frequency signal and the power supply voltage VCC from the SiP module 205 are transmitted to the amplifier module 240 through power wiring lines 251 and 252 disposed in the dielectric substrate 230. Output power Pout amplified in the power amplifier circuit 100 is transmitted to the radiating element 220 through a power wiring line 267 disposed on the main surface 232 of the dielectric substrate 230.

The Si-based material that is relatively inexpensive and that is appropriate for mass manufacturing is generally used as the semiconductor substrate for forming a semiconductor device used in the amplifier. However, since the Si-based material tends to have increased loss in the sub-terahertz frequency band of 100 GHz or more, the Si-based material can be in a state in which characteristics required for the semiconductor device are not realized.

In contrast, the Group III-V compound, such as GaN, GaAs, or InP, has higher unit price than that of the Si-based material but has higher power density than that of the Si-based material. Accordingly, the material of the Group III-V compound has the loss that is lower than that of the substrate of the Si-based material even in the sub-terahertz frequency band. Consequently, forming the final-stage amplifier 120 through which relatively large current flows in the amplifier module 240 on the semiconductor substrate 242 containing the material of the low-loss Group III-V compound and forming the other circuits on the semiconductor substrate 241 containing the Si-based material enable the circuit efficiency to be improved while suppressing increase in the cost.

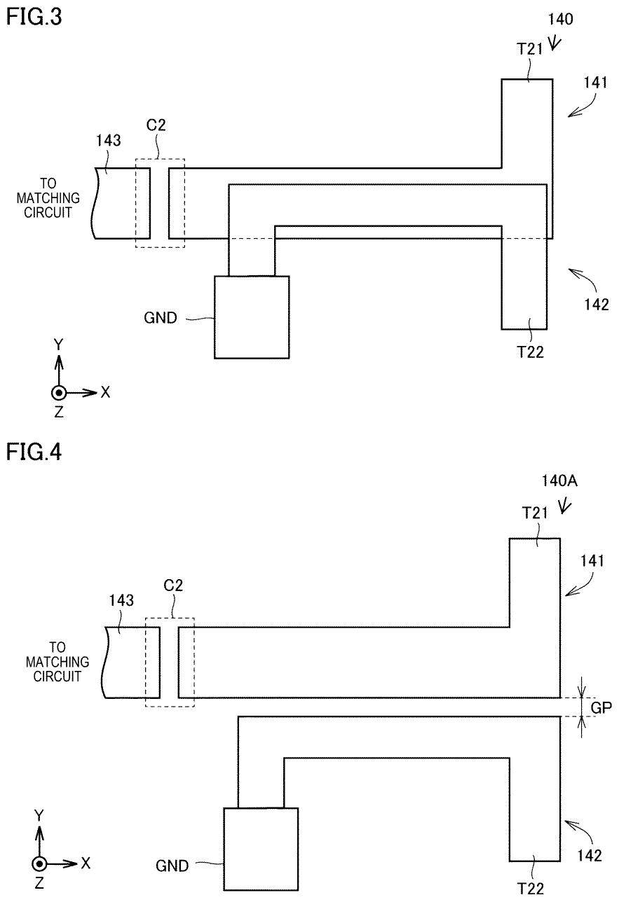

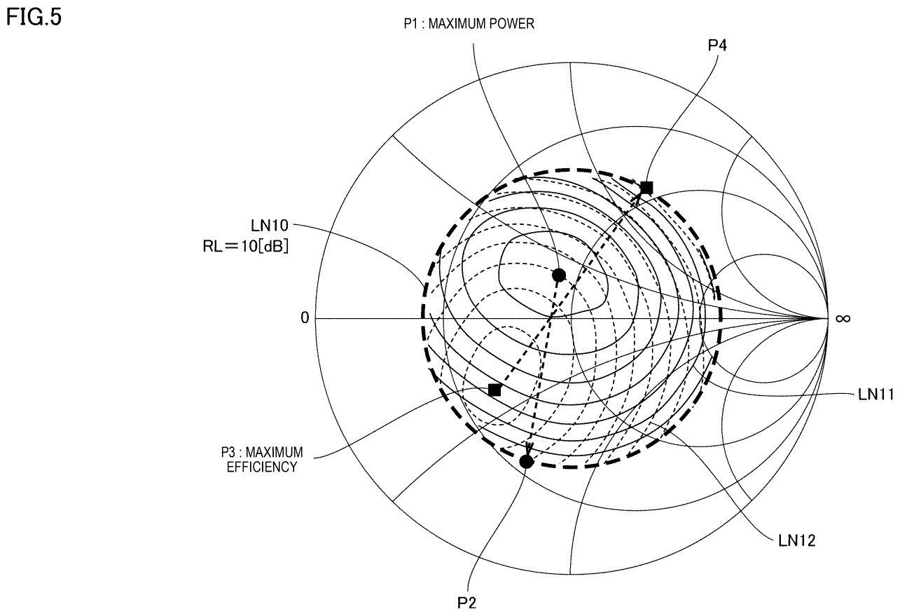

FIG. 3 and FIG. 4 are diagrams illustrating examples of the arrangement of the balun 140 formed on or in the semiconductor substrate 241. In the examples in FIG. 3 and FIG. 4, the line 141 composing the balun 140 is a strip-shaped plate electrode having a substantially L shape and the line 142 composing the balun 140 is a strip-shaped plate electrode having a substantially U shape.

One end of the line 141 is disposed on or in the semiconductor substrate 241 so as to be apart from a line 143 connected to the matching circuit 130 with a small gap sandwiched between the line 141 and the line 143. The gap portion between the line 141 and the line 143 forms the capacitor C2. The line 141 extends from an end portion at which the capacitor C2 is formed in the positive direction of the X axis and bends in the Y-axis direction. The other end of the line 141 is connected to the terminal T21 of the output terminal T2.

One end of the line 142 is connected to an electrode connected to the ground potential GND. The line 142 protrudes from the electrode in the positive direction of the Y axis, extends in the positive direction of the X axis, and bends in the negative direction of the Y axis. The other end of the line 142 is connected to the terminal T22 of the output terminal T2.

In the example in FIG. 3, in a plan view from the normal direction (the Z-axis direction) of the semiconductor substrate 241, the portions that extend in the Y-axis direction of the line 141 and the line 142 are overlapped with each other. In other words, the line 142 is disposed on a layer different from the layer of the line 141 in the semiconductor substrate 241. Alternatively, the line 142 may be disposed above the semiconductor substrate 241 with an air gap sandwiched between the line 142 and the line 141 with respect to the line 141 disposed on the semiconductor substrate 241. Disposing the line 141 and the line 142 so that the partial portions of the two lines are overlapped with each other in the above manner causes the line 141 and the line 142 to be coupled to each other. As a result, the signal having the phase inverted with respect to that of the signal transmitted through the line 141 is induced on the line 142.

In the example in FIG. 4, the line 142 is disposed on the same layer as that of the line 141 in the semiconductor substrate 241 so as to be adjacent to the line 141. More specifically, the portion that extends in the Y-axis direction of the line 142 is disposed along the portion that extends in the Y-axis direction of the line 141 so as to be apart from the portion that extends in the Y-axis direction of the line 141 with a gap GP therebetween. Juxtaposing the partial portions of the two lines in the above manner causes the line 141 and the line 142 to be coupled to each other.

(Relationship of Efficiency and Output Power with Respect to Load)

In a radio communication apparatus, development of communication in the sub-terahertz frequency band of 100 GHZ or more has been advanced in recent years. Since use of the sub-terahertz frequency band enables the spectrum band width to be broadened, it is possible to realize high-speed communication of large capacity of, for example, 100 Gbps or more.

On the other hand, the loss on a transmission path of a signal is increased and the characteristics of the amplifier itself tend to be degraded as the frequency of the radio-frequency signal to be transmitted is increased. Accordingly, with the object of reduction in the loss, it is desirable that the signal transmission path between the amplifier and the antenna be shortened as much as possible and the number of the devices disposed on the signal transmission path be decreased as much as possible. In addition, the size of the radiating element is further decreased to decrease the entire size of the transmission circuit as the frequency is increased. Accordingly, it is necessary to make integrated design of the power amplifier circuit and the antenna, instead of individually designing the power amplifier circuit and the antenna.

The power amplifier is normally designed so as to operate at fixed load, such as 50Ω. However, practically, load fluctuation may occur due to proximity of an external object, such as a hand, to the antenna. In the case of an array antenna using multiple radiating elements, the load fluctuation caused by unnecessary mutual coupling between the antennas may occur in beam forming. If such load fluctuation occurs, the Q value is decreased due to return loss caused by the difference from the impedance in design to reduce antenna characteristics. Since the influence of the load fluctuation becomes obvious when the signal transmission path between the amplifier and the antenna is shortened in the above manner, desired characteristics are not necessarily realized or output current from the amplifier may be varied to cause deterioration or failure of the amplifier.

FIG. 5 is a diagram for describing an example of variation in power and efficiency when the amplifier is directly connected to the radiating element via the matching circuit. Referring to FIG. 5, the result of simulation of the variation in power and efficiency in an area where the return loss is 10 dB or more (an area inside a broken line LN10 in FIG. 5) is indicated using contour lines on a Smith chart. The power is indicated using solid-line contour lines LN11 and the maximum power is achieved at a point P1. The efficiency is indicated using broken-lie contour lines LN12 and the maximum efficiency is achieved at a point P3.

The contour lines of the power are indicated at 0.5 dB intervals. The contour lines of the efficiency are indicated at 4% intervals. Accordingly, in an area where the return loss of the antenna is 10 dB or more, the power is decreased by 4 dB and the efficiency is decreased by 40% due to the load fluctuation. In order to compensate the reduction in the characteristics with the amplifier, variation in current of one ampere or more is required in the amplifier.

The range of variation of the output power in the amplifier is generally required to be 1 dB or less. Accordingly, in the configuration in which the amplifier is directly connected to the radiating element, it is necessary to use the circuit in an area where the return loss of the radiating element is further increased.

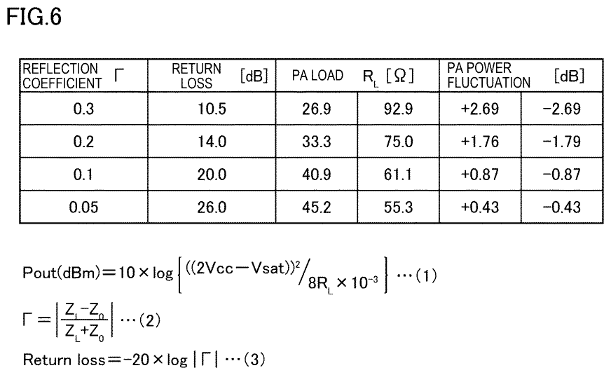

FIG. 6 is a table for describing the load fluctuation and power fluctuation of the amplifier when a reflection coefficient (the return loss) of the radiating element is varied. Referring to FIG. 6, the output power Pout in saturated output of the amplifier is represented by Equation (1), where an antenna load is denoted by RI, the power supply voltage is denoted by V_{cc}, and saturated voltage is denoted by Vₛₐₜ:

$$Pout ( dBm ) = 10 \times log \{ {( ( 2 Vcc - Vsat ) )}^{2} / 8 {R}_{L} \times {10}^{- 3} \} \qquad ( 1 )$$

A reflection coefficient Γ and the return loss are represented by Equation (2) and Equation (3), respectively, where the characteristic impedance is denoted by Z₀ (=50δ) and the impedance of the antenna load is denoted by Z_{L}:

$$Γ = \vert \frac{{Z}_{L} - {Z}_{0}}{{Z}_{L} + {Z}_{0}} \vert \qquad ( 2 )$$

$$Return loss = - 20 \times log \vert Γ \vert \qquad ( 3 )$$

According to Equation (1) to Equation (3), the return loss, the load fluctuation of the amplifier, and the power fluctuation of the amplifier when the reflection coefficient Γ is varied are indicated in FIG. 6. Since the power fluctuation of the amplifier is required to be 1 dB or less, as described above, it is necessary to design the antenna so that the absolute value of Γ is 0.05 or less in a frequency band to be transmitted, that is, so that the return loss is 26 dB or more in order to set the value of the power fluctuation to 1 dB or less.

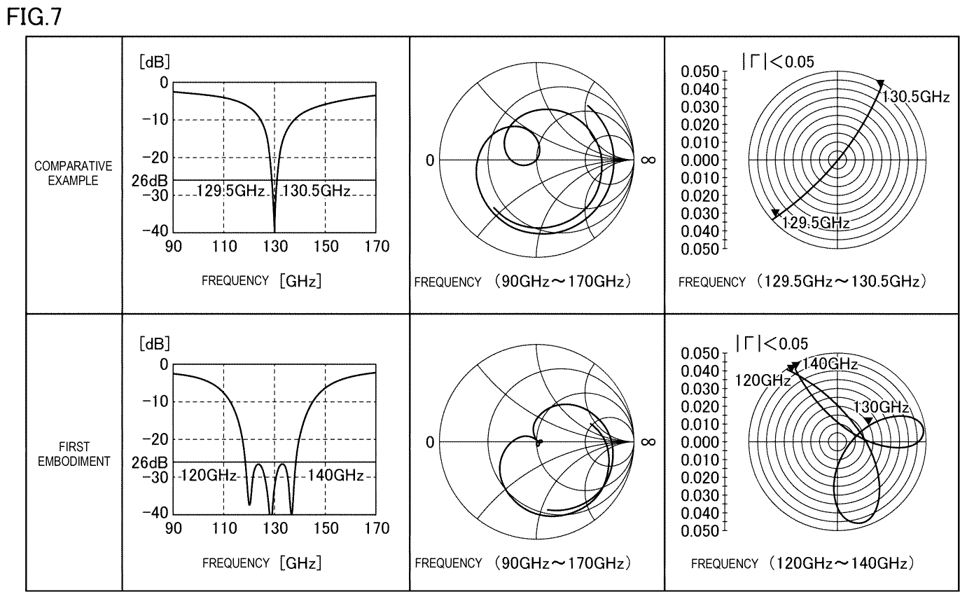

FIG. 7 includes diagrams for describing the antenna characteristics in a comparative example in which the radiating element itself is connected to the amplifier and in the case in which the radiating element is connected to the amplifier via the balun, as in the transmission circuit 10 of the first embodiment. Referring to FIG. 7, the upper diagrams indicate the characteristics in the comparative example and the lower diagrams indicate the characteristics in the case of the transmission circuit 10 of the first embodiment.

In each of the upper diagrams and the lower diagrams in FIG. 7, the left diagram indicates the return loss when the load side (the radiating element side) is viewed from the output end of the amplifier, the intermediate diagram is the Smith chart indicating the variation in impedance when the frequency is varied from 90 GHz to 170 GHz, and the right diagram results from enlargement of a range of |Γ|<0.05 in the Smith chart in the intermediate diagram.

In the case of the comparative example (the upper diagrams), that is, in the resonance caused by the radiating element itself, the frequency band capable of achieving the return loss of 26 dB or more is a range from 129.5 GHZ to 130.5 GHZ. In other words, the frequency band capable of suppressing the fluctuation in the output power from the amplifier to 1 dB or less even if the load fluctuation occurs at the antenna is the range from 129.5 GHZ to 130.5 GHz. Accordingly, it is possible to ensure a desired Q value only in a narrow band width of 1 GHz in the comparative example.

In contrast, in the case of the transmission circuit 10 of the first embodiment, the return loss of 26 dB or more is achieved in a range from 120 GHz to 140 GHz by causing poles by the resonance of the balun, in addition to the resonance of the radiating element. In other words, for the signal of the frequency from 120 GHz to 140 GHz, the fluctuation in the output power from the amplifier is capable of being suppressed to 1 dB or less even if the load fluctuation of the antenna occurs. As a result, it is possible to ensure a desired Q value in a wide band width of 20 GHz and it is possible to suppress the change in characteristics caused by the load fluctuation over a wide band in the transmission circuit.

In order to achieve the characteristics described above, it is important to form the balun not on the dielectric substrate but on the semiconductor substrate. In order to realize a desired resonant frequency in the balun, it is necessary to set the line length of each line and the gap between the lines with high dimensional accuracy. Particularly, since the wavelength of the signal is further shortened in the case of the sub-terahertz frequency band, compared with the signal of millimeter waves or the likes, the influence of dimension error of the lines is increased.

When the resin substrate or the ceramic substrate is used, since heating and/or pressing is performed in the manufacturing process of the substrate, deformation, such as expansion or contraction, of the base material is likely to occur. Accordingly, in the formation of the balun on the dielectric substrate, it may be difficult to realize a desired dimensional accuracy for each line.

In contrast, the formation of the line on the semiconductor substrate is generally realized by a photographic technique, such as exposure or etching. In other words, when the balun is formed on the semiconductor substrate, fine processing is easily performed, compared with the case in which the dielectric substrate is used. Accordingly, forming the balun on the semiconductor substrate enables each line to be formed with higher dimensional accuracy, compared with the case in which the balun is formed on the dielectric substrate. Consequently, in the transmission circuit targeting at the sub-terahertz frequency band in the first embodiment, it is possible to easily realize desired characteristics by forming the balun on the semiconductor substrate.

As described above, in the design of the transmission circuit targeting at the radio-frequency signal in the sub-terahertz frequency band, performing not individual optimization of the characteristics of the antenna and the characteristics of the amplifier but optimization of integrated configuration of the antenna and the amplifier enables the influence on the amplifier involved in the load fluctuation of the antenna to be suppressed over a wide band width.

The “amplifier 110” and the “amplifier 120” in the first embodiment correspond to a “first amplifier” and a “second amplifier” in the present disclosure, respectively. The “terminal T21” and the “terminal T22” in the first embodiment correspond to a “first output terminal” and a “second output terminal” in the present disclosure, respectively. The “line 141” and the “line 142” in the first embodiment correspond to the “first line” and the “second line” in the present disclosure, respectively. The “semiconductor substrate 241” and the “semiconductor substrate 242” in the first embodiment correspond to a “first substrate” and a “second substrate” in the present disclosure, respectively.

### First Modification

In a first modification, different arrangement configuration of the devices in the dielectric substrate 230 will be described.

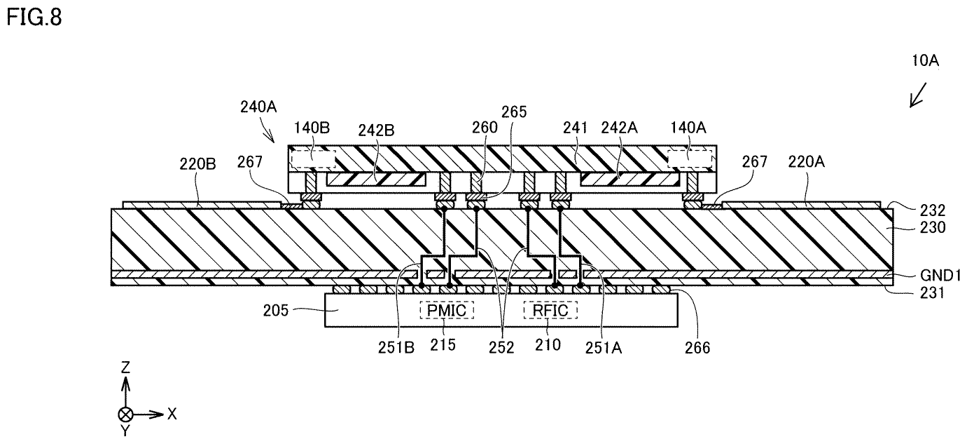

FIG. 8 is a transparent side view of a transmission circuit 10A of the first modification. The transmission circuit 10A has a configuration in which multiple radiating elements 220A and 20B are disposed on the main surface 232 of the dielectric substrate 230 and the SiP module 205 is disposed on the main surface 231 of the dielectric substrate 230.

The dimension in the X-axis direction of the dielectric substrate 230 in the transmission circuit 10A is greater than that in the transmission circuit 10 of the first embodiment. The radiating element 220A and the radiating element 220B are disposed in the positive direction and the negative direction, respectively, of the X axis with respect to an amplifier module 240A on the main surface 232.

The amplifier module 240A includes the circuits for the two radiating elements. Specifically, a semiconductor substrate 242A on which the final-stage amplifier for the radiating element 220A is formed and a semiconductor substrate 242B on which the final-stage amplifier for the radiating element 220B is formed are disposed on the semiconductor substrate 241. Baluns 140A and 140B for the radiating elements 220A and 220B, respectively, are formed on the semiconductor substrate 241.

The radio-frequency signals for the radiating elements 220A and 202B are supplied from the SiP module 205 disposed on the main surface 231 of the dielectric substrate 230 to the amplifier module 240A through power wiring lines 251A and 251B, respectively. In addition, the power supply voltage VCC for the radiating elements 220A and 202B is supplied to the semiconductor substrate 242A through the power wiring lines 252.

A ground wiring line for the amplifier module 240A is connected to the ground electrode GND1 in the dielectric substrate 230, although not illustrated in FIG. 8.

Also with such a configuration, disposing the baluns formed on the semiconductor substrate on the transmission paths between the amplifiers and the antennas to design the integrated configuration of the baluns and the antennas enables the influence on the amplifier involved in the load fluctuation of the antenna to be suppressed over a wide band width.

### Second Modification

In a second modification, a configuration will be described in which the radiating element is disposed on the semiconductor substrate in the amplifier module.

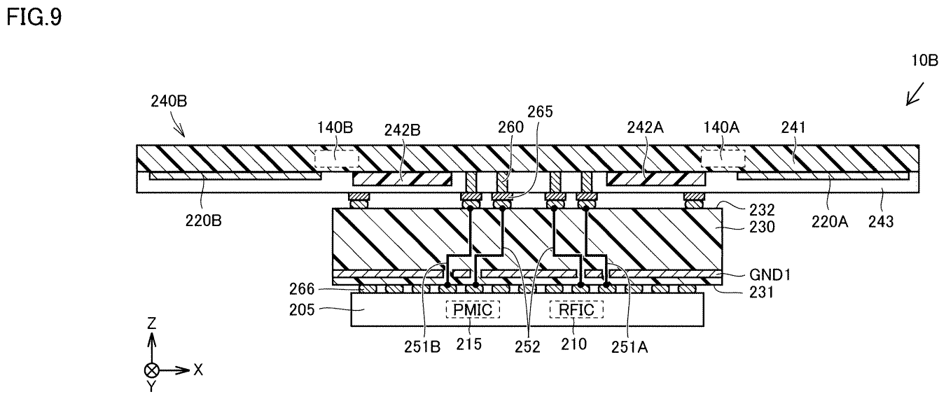

FIG. 9 is a transparent side view of a transmission circuit 10B of the second modification. In the transmission circuit 10B, the SiP module 205 is disposed on the main surface 231 of the dielectric substrate 230, as in the transmission circuit 10A of the first modification. Instead of the amplifier module 240A, an amplifier module 240B is disposed on the main surface 232.

In the amplifier module 240B, the dimension in the X-axis direction of the semiconductor substrate 241 is enlarged and the radiating element 220A and the radiating element 220B are disposed on the semiconductor substrate 241. More specifically, the radiating element 220A is disposed in the positive direction of the X axis with respect to the semiconductor substrate 242A on the semiconductor substrate 241. The radiating element 220B is disposed in the negative direction of the X axis with respect to the semiconductor substrate 242B.

The radio-frequency signal amplified by the amplifier 120 formed on the semiconductor substrate 242A is supplied to the radiating element 220A through the balun 140A. Similarly, the radio-frequency signal amplified by the amplifier 120 formed on the semiconductor substrate 242B is supplied to the radiating element 220B through the balun 140B.

In the transmission circuit 10B, since the ground electrode is not capable of being disposed so as to be opposed to the radiating elements 220A and 220B on the semiconductor substrate 241, not the patch antennas but two-power-supply end-fire antennas, such as the dipole antennas, are used as the radiating elements 220A and 220B. The dimension in the X-axis direction of the dielectric substrate 230 is shortened not to block the radiation of the radio waves from the radiating element 220, and the amplifier module 240B protrudes from the end portions in the X-axis direction of the dielectric substrate 230. In other words, in a plan view from the normal direction of the dielectric substrate 230, the radiating elements 220A and 220B are disposed so as not to be overlapped with the dielectric substrate 230.

Also with such a configuration, disposing the baluns formed on the semiconductor substrates on the transmission paths between the amplifiers and the antennas to design the integrated configuration of the baluns and the antennas enables the influence on the amplifier involved in the load fluctuation of the antenna to be suppressed over a wide band width.

### Second Embodiment

In a second embodiment, another configuration of the balun will be described.

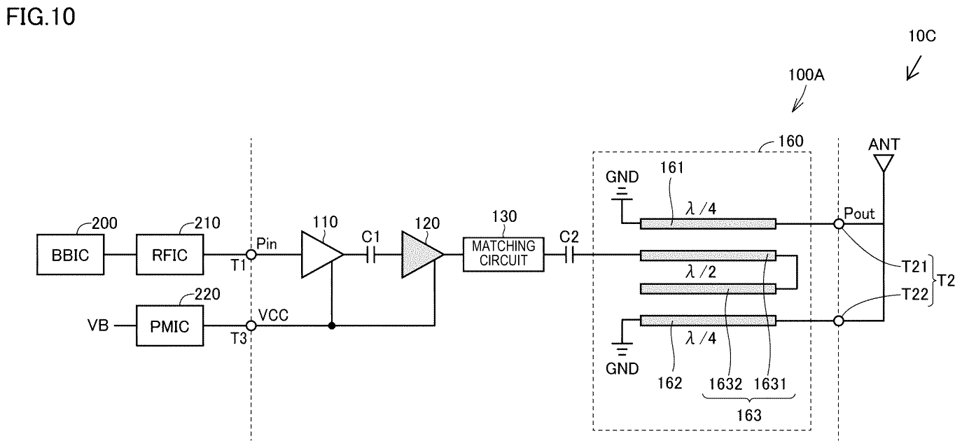

FIG. 10 is a circuit diagram of a transmission circuit 10C to which a power amplifier circuit 100A according to the second embodiment is applied. The transmission circuit 10C has a configuration in which the balun 140 in the first embodiment is replaced with a balun 160. More specifically, instead of the two-line choke balun of the balun 140, a three-line Marchand balun is adopted for the balun 160.

The balun 160 is composed of lines 161 and 162 each having a length of λ/4 and a line 163 having a length of λ/2. One end of the line 161 is connected to the terminal T21 and the other end thereof is connected to the ground potential GND. Similarly, one end of the line 162 is connected to the terminal T22 and the other end thereof is connected to the ground potential GND.

The line 163 includes partial lines 1631 and 1632, one ends of which are connected to each other. The other end of the partial line 1631 is connected to the capacitor C2. The other end of the partial line 1632 is an open end. The partial line 1631 is coupled to the line 161 and the partial line 1632 is coupled to the line 162.

The respective lines 141 and 142 are disposed so that the direction of current flowing through the line 161 and the line 162 is opposite to the direction of current flowing through the line 163. Accordingly, the radio-frequency signals having the phases inverted are outputted from the line 161 and the line 162.

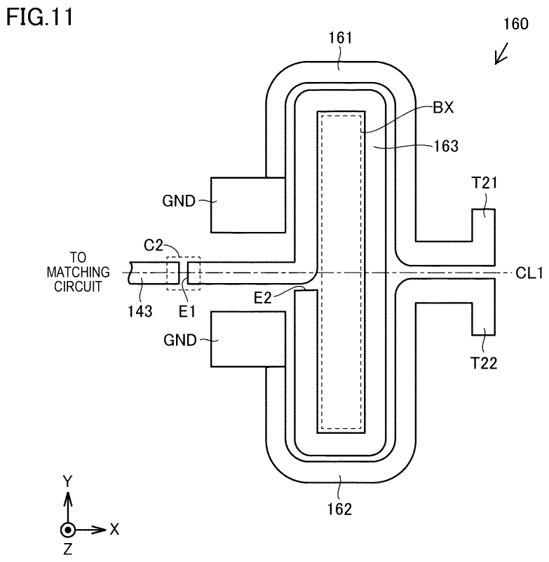

FIG. 11 is a plan view of an example of the balun 160 in FIG. 10. As described above, the balun 160 is composed of the three lines 161 to 163 formed on the semiconductor substrate 241. The entire shape of the balun 160 is substantially line-symmetric to a virtual line CL1 extending in the X-axis direction.

The line 163 is a strip-shaped electrode having an end portion E1 and an end portion E2. The line 163 extends in the positive direction of the X axis from the end portion E1 and is wound clockwise along the outer periphery of a virtual rectangle BX. The end portion E1 is disposed so as to be apart from the line 143 connected to the matching circuit 130 in FIG. 10 with a small gap sandwiched between the end portion E1 and the line 143. The gap portion between the end portion E1 of the line 163 and the line 143 forms the capacitor C2. The end portion E2 is an open end.

The line 161 is a strip-shaped electrode disposed along the portion in the positive direction of the Y axis of the line 163. One end of the line 161 is connected to an electrode connected to the ground potential GND. The line 161 extends along the line 163, protrudes from the line 163 in the positive direction of the X axis, and bends in the positive direction of the Y axis. The other end of the line 161 is connected to the terminal T21 of the output terminal T2.

The line 162 is a strip-shaped electrode disposed along the portion in the negative direction of the Y axis of the line 163. One end of the line 162 is connected to an electrode connected to the ground potential GND. The line 162 extends along the line 163, protrudes from the line 163 in the positive direction of the X axis, and bends in the negative direction of the Y axis. The other end of the line 162 is connected to the terminal T22 of the output terminal T2.

The lines 161 and 162 are coupled to the line 163 at the adjacent portions along the line 163. Accordingly, the radio-frequency signal transmitted to the end portion E1 of the line 163 is transmitted to the lines 161 and 162 and is transmitted to the antenna ANT through the output terminal T2 (the terminals T21 and T22) as the differential signal.

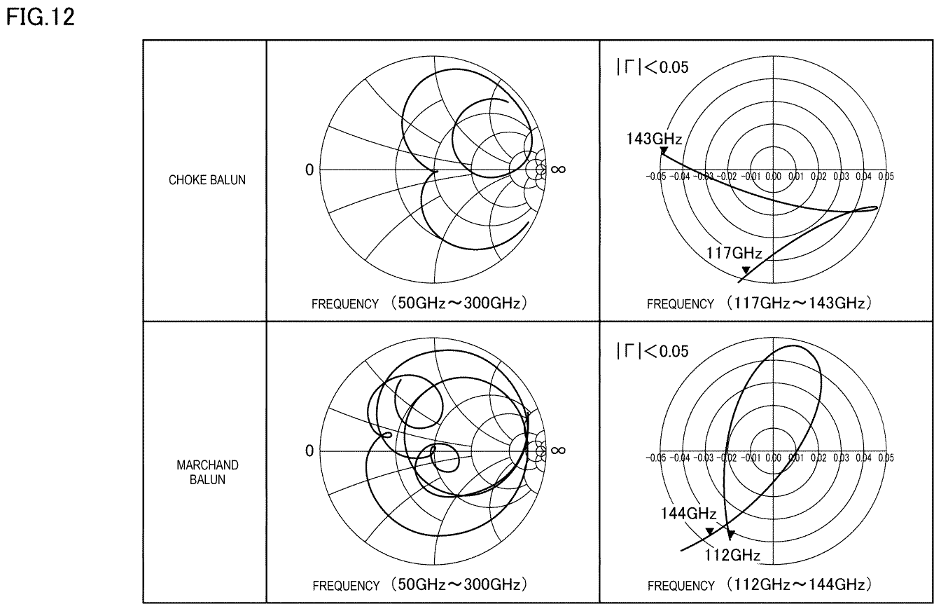

FIG. 12 includes diagrams for describing impedance change of the choke balun of the first embodiment and the Marchand balun of the second embodiment. The upper diagrams in FIG. 12 indicate the impedance change of the choke balun itself of the first embodiment. The lower diagrams indicate the impedance change of the Marchand balun itself of the second embodiment. In each of the upper diagrams and the lower diagrams, the left diagram is the Smith chart indicating the impedance change when the frequency is varied from 50 GHz to 300 GHz and the right diagram results from enlargement of a range of |Γ|<0.05 in the Smith chart in the left diagram.

In the case of the choke balun (the balun 140) of the first embodiment, the frequency band achieving the range of |Γ|<0.05 is a range from 117 GHz to 143 GHZ. In contrast, in the case of the Marchand balun (the balun 160) of the second embodiment, the frequency band achieving the range of |Γ|<0.05 is a range from 112 GHz to 144 GHZ and the Marchand balun has a characteristic similar to that of the choke balun.

As described above, also when the Marchand balun is used as the balun disposed between the amplifiers and the radiating element, it is possible to suppress the influence on the amplifier involved in the load fluctuation of the antenna over a wide band width.

### Aspects

The multiple exemplary embodiments described above are understanded by persons skilled in the art as specific examples of the following aspects.

(Section 1) A power amplifier circuit according to an aspect includes an input terminal, a first output terminal and a second output terminal, a first amplifier and a second amplifier, a balun, and a semiconductor substrate. The first amplifier amplifies a radio-frequency signal received at the input terminal. The second amplifier further amplifies the radio-frequency signal amplified by the first amplifier. The balun is connected to the second amplifier and converts an unbalanced line into a first balanced line and a second balanced line. The first amplifier and the second amplifier are formed on the semiconductor substrate. The first balanced line is connected to the first output terminal. The second balanced line is connected to the second output terminal. A frequency of a radio-frequency signal to be transmitted is 100 GHz or more. The balun is formed on the semiconductor substrate.

(Section 2) In the power amplifier circuit described in Section 1, the balun is a choke balun including a first line and a second line coupled to the first line. One end of the first line is connected to the unbalanced line and the other end thereof is connected to the first balanced line. One end of the second line is connected to the second balanced line and the other end thereof is connected to ground potential. When a wavelength of the radio-frequency signal to be transmitted is denoted by λ, the first line and the second line each have a line length of λ/4. A phase of the radio-frequency signal transmitted on the second line is inverted from a phase of the radio-frequency signal transmitted on the first line.

(Section 3) In the power amplifier circuit described in Section 2, in a plan view of the semiconductor substrate from a normal direction, the first line and the second line are partially overlapped with each other.

(Section 4) In the power amplifier circuit described in Section 2, in a plan view of the semiconductor substrate from a normal direction, the first line and the second line are disposed so as to be adjacent to each other.

(Section 5) In the power amplifier circuit described in Section 1, the balun is a Marchand balun including a third line, a fourth line, and a fifth line coupled to the third line and the fourth line. One end of the third line is connected to the first balanced line and the other end thereof is connected to ground potential. One end of the fourth lien is connected the second balanced line and the other end thereof is connected to the ground potential. One end of the fifth line is connected the unbalanced line and the other end thereof is an open end. When a wavelength of the radio-frequency signal to be transmitted is denoted by λ, the third line and the fourth line each have a line length of λ/4 and the fifth line has a line length of λ/2.

(Section 6) In the power amplifier circuit described in Section 5, the fifth line has a first portion and a second portion that are connected in series to each other. The third line is coupled to the first portion. The fourth line is coupled to the second portion. A phase of the radio-frequency signal transmitted on the third line is inverted from a phase of the radio-frequency signal transmitted on the fourth line.

(Section 7) In the power amplifier circuit described in any of Section 1 to Section 6, the semiconductor substrate includes a first substrate and a second substrate. The first amplifier is formed on the first substrate. The second amplifier is formed on the second substrate. The first substrate is a semiconductor substrate containing a material having an Si-based based material as a major component. The second substrate is a semiconductor substrate containing a material having a compound of a Group III element and a Group V element as the major component.

(Section 8) In the power amplifier circuit described in Section 7, the balun is formed on the first substrate.

(Section 9) A transmission circuit according to an aspect includes the power amplifier circuit described in any of Section 1 to Section 8, a radiating element connected to the first output terminal and the second output terminal, and a power supply circuit that supplies a radio-frequency signal to the power amplifier circuit.

(Section 10) The transmission circuit described in Section 9 further includes a dielectric substrate having a first surface and a second surface that are opposed to each other. The power amplifier circuit, the power supply circuit, and the radiating element are disposed on the first surface.

(Section 11) The transmission circuit described in Section 9 further includes a dielectric substrate having a first surface and a second surface that are opposed to each other. The power amplifier circuit and the radiating element are disposed on the first surface. The power supply circuit is disposed on the second surface.

(Section 12) The transmission circuit described in Section 9 further includes a dielectric substrate having a first surface and a second surface that are opposed to each other. The power amplifier circuit and the power supply circuit are disposed on the dielectric substrate. The radiating element is disposed on the semiconductor substrate.

(Section 13) A power amplifier circuit according to an aspect includes an input terminal, a first output terminal and a second output terminal, a first amplifier and a second amplifier, a balun, and a semiconductor substrate. The first amplifier amplifies a radio-frequency signal received at the input terminal. The second amplifier further amplifies the radio-frequency signal amplified by the first amplifier. The balun is connected to the second amplifier and converts an unbalanced line into a first balanced line and a second balanced line. The first amplifier and the second amplifier are formed on the semiconductor substrate. The first balanced line is connected to the first output terminal. The second balanced line is connected to the second output terminal. The balun is formed on the semiconductor substrate.

The disclosed embodiments are only examples in all the points and should be considered not to be restrictive. The scope of the present disclosure is not defined by the description of the above embodiments but is defined by the claims and is intended to include meanings equivalent to the range of the claims and all the modifications within the range of the claims.
10, 10A to 10C transmission circuit
100, 100A power amplifier circuit
110, 120 amplifier
130 matching circuit
140, 140A, 140B, 160 balun
141 to 143, 161 to 163 line
1631, 1632 partial line
200 BBIC
205 SiP module
210 RFIC
220, 220A, 220B radiating element
230 dielectric substrate
231, 232 main surface
240, 240A, 240B amplifier module
241, 242, 242A, 242B semiconductor substrate
243 resin
251, 251A, 251B, 252, 267 power wiring line
260 columnar electrode
265 connection electrode
266 solder bump
ANT antenna
C1, C2 capacitor
E1, E2 end portion
GND ground potential
GND1 ground electrode
GP gap
T1 input terminal
T2 output terminal
T3 power terminal
T21, T22 terminal

1. A power amplifier circuit comprising:
an input terminal;
a first output terminal and a second output terminal;
a first amplifier configured to amplify a radio-frequency signal received at the input terminal;
a second amplifier configured to further amplify the radio-frequency signal amplified by the first amplifier;
a balun that is connected to the second amplifier and that is configured to convert an unbalanced line into a first balanced line and a second balanced line; and
a semiconductor substrate on which the first amplifier and the second amplifier are arranged,
wherein the first balanced line is connected to the first output terminal,
wherein the second balanced line is connected to the second output terminal,
wherein a frequency of the radio-frequency signal is 100 GHZ or more, and
wherein the balun is on the semiconductor substrate.

2. The power amplifier circuit according to claim 1,
wherein the balun is a choke balun comprising a first line and a second line coupled to the first line,
wherein a first end of the first line is connected to the unbalanced line and a second end of the first line is connected to the first balanced line,
wherein a first end of the second line is connected to the second balanced line and a second end of the second line is connected to ground potential,
wherein the first line and the second line each have a line length of λ/4, λ being a wavelength of the radio-frequency signal, and
wherein a phase of the radio-frequency signal transmitted on the second line is inverted from a phase of the radio-frequency signal transmitted on the first line.

3. The power amplifier circuit according to claim 2, wherein, in a plan view of the semiconductor substrate from a normal direction, the first line and the second line are partially overlapped with each other.

4. The power amplifier circuit according to claim 2, wherein, in a plan view of the semiconductor substrate from a normal direction, the first line and the second line are adjacent to each other.

5. The power amplifier circuit according to claim 1,
wherein the balun is a Marchand balun comprising a third line, a fourth line, and a fifth line coupled to the third line and the fourth line,
wherein a first end of the third line is connected to the first balanced line and a second end of the third line is connected to ground potential,
wherein a first end of the fourth line is connected the second balanced line and a second end of the fourth line is connected to ground potential,
wherein a first end of the fifth line is connected the unbalanced line and a second end of the fifth line is an open end, and
wherein the third line and the fourth line each have a line length of λ/4 and the fifth line has a line length of >/2, λ being a wavelength of the radio-frequency signal.

6. The power amplifier circuit according to claim 5,
wherein the fifth line has a first portion and a second portion that are connected in series to each other,
wherein the third line is coupled to the first portion,
wherein the fourth line is coupled to the second portion, and
wherein a phase of the radio-frequency signal transmitted on the third line is inverted from a phase of the radio-frequency signal transmitted on the fourth line.

7. The power amplifier circuit according to claim 1,
wherein the semiconductor substrate comprises a first substrate and a second substrate,
wherein the first amplifier is on the first substrate,
wherein the second amplifier is on the second substrate,
wherein the first substrate is a semiconductor substrate containing a material having an Si-based based material as a major component, and
wherein the second substrate is a semiconductor substrate containing a material having a compound of a Group III element and a Group V element as the major component.

8. The power amplifier circuit according to claim 7, wherein the balun is on the first substrate.

9. A transmission circuit comprising:
the power amplifier circuit according to claim 1;
a radiating element connected to the first output terminal and the second output terminal; and
a power supply circuit configured to supply a radio-frequency signal to the power amplifier circuit.

10. The transmission circuit according to claim 9, further comprising:
a dielectric substrate having a first surface and a second surface that are opposed to each other,
wherein the power amplifier circuit, the power supply circuit, and the radiating element are on the first surface.

11. The transmission circuit according to claim 9, further comprising:
a dielectric substrate having a first surface and a second surface that are opposed to each other,
wherein the power amplifier circuit and the radiating element are on the first surface, and
wherein the power supply circuit is on the second surface.

12. The transmission circuit according to claim 9, further comprising:
a dielectric substrate having a first surface and a second surface that are opposed to each other,
wherein the power amplifier circuit and the power supply circuit are on the dielectric substrate, and
wherein the radiating element is on the semiconductor substrate.

13. A power amplifier circuit comprising:
an input terminal;
a first output terminal and a second output terminal;
a first amplifier configured to amplify a radio-frequency signal received at the input terminal;
a second amplifier configured to further amplify the radio-frequency signal amplified by the first amplifier;
a balun that is connected to the second amplifier and that is configured to convert an unbalanced line into a first balanced line and a second balanced line; and
a semiconductor substrate on which the first amplifier and the second amplifier are arranged,
wherein the first balanced line is connected to the first output terminal,
wherein the second balanced line is connected to the second output terminal, and
wherein the balun is on the semiconductor substrate.
